(19) United States
(12) Patent Application Publication
(10) Pub. No.: US 2012/0145215 A1
(43) Pub. Date: Jun. 14, 2012

(54) Thermoelectric module and method of sealing the same

(75) Inventors: Youngnam HWANG, Suwon-si (KR); Hyunjik YANG, Suwon-si (KR); Dongik SHIN, Hwaseong-si (KR)

(73) Assignee: SAMSUNG ELECTRO-MECHANICS CO., LTD., Suwon (KR)

(21) Appl. No.: 13/064,725

(22) Filed: Apr. 11, 2011

(30) Foreign Application Priority Data
Dec. 14, 2010 (KR) 10-2010-0127344

(51) Int. Cl. H01L 35/02; H01L 35/34; C23C 16/02; H01L 35/28

(52) U.S. Cl. 136/232; 136/201; 427/255.6

(57) ABSTRACT

Disclosed herein is a thermoelectric module including an insulating sealing part formed on portions of a thermoelectric module part or the entirety thereof, the thermoelectric module part including thermoelectric elements, electrodes, and substrates, and a method of sealing the thermoelectric module using a parylene coating method. When the thermoelectric module is coated with parylene, which is a new material having insulation, the parylene is penetrated between the thermoelectric elements to form an insulating separator. The insulating separator efficiently prevents corrosion due to water adsorption, thereby making it possible to improve reliability of the thermoelectric module.

### CROSS REFERENCE(S) TO RELATED APPLICATIONS

This application claims the benefit under 35 U.S.C. Section [120, 119, 119(e)] of Korean Patent Application Serial No. 10-2010-0127344, entitled “Thermoelectric Module And Method Of Sealing The Same” filed on Dec. 14, 2010, which is hereby incorporated by reference in its entirety into this application.

### BACKGROUND OF THE INVENTION

1. Technical Field

The present invention relates to a thermoelectric module and a method of sealing the same, and more particularly, to a thermoelectric module configured by changing a sealing method thereof and a method of sealing the same.

2. Description of the Related Art

Generally, a thermoelectric module is divided into a module part including thermoelectric elements, electrodes, and ceramic substrates, and a power supply unit supplying DC power to the module.

FIG. 1 shows a structure of a module part excepting a power supply unit. As thermoelectric elements, N-type semiconductors 11 and P-type semiconductors 12 are generally used. A module is configured by arranging a plurality of N-type semiconductors 11 and P-type semiconductors 12, which form pairs, on a plane and then connecting them again in series using metal electrodes 13 and 14.

When current is applied to the module, electrons (e−) and holes (h+), which are carriers, are generated from a metal electrode on one side, such that the electrons flow to the N-type semiconductors and the holes flow to the P-type semiconductor, respectively, while transferring heat, and then these carriers are recombined at a metal electrode on the other side.

Heat-absorption occurs from the electrodes in which carriers are generated and a substrate 15 adjacent thereto and heat-generation occurs from the electrodes in which the carriers are recombined and a substrate 16 adjacent thereto. In this case, each portion is called a cold side and a hot side and configures both surfaces of the thermoelectric module.

When the thermoelectric module including the substrates, the electrodes, and the thermoelectric elements as shown in FIG. 1 is driven, water vapor is penetrated therein causing internal corrosion, such that defects may be generated. Therefore, water adsorption when using the thermoelectric module is one of the most important factors related to thermoelectric reliability.

Reviewing the related arts for preventing the problems, the surroundings of the module is sealed 21a and 21b using silicon or epoxy as shown in FIG. 2. Although, with the sealing method according to the related art, it is difficult to seal four surfaces in an automation operation, thus, the process of applying silicon or epoxy is manually performed which causes inconvenience in work and degradation in productivity, thereby increasing the manufacturing costs thereof. In addition, when a worker manually performs the process, a lot of time may be rendered therefor and defects may be determined according to work proficiency of the worker.

In addition, epoxy is weak against waterproof and corrosion. Therefore, when the module is exposed to the outside such as, being underwater or contacting gas for a long time, the electrodes or the epoxy is damaged due to electrolysis or reaction with gas which causes defects of the module, thereby degrading reliability of the product.

### SUMMARY OF THE INVENTION

An object of the present invention is to provide a thermoelectric module with improved reliability.

Another object of the present invention is to provide a method of sealing the thermoelectric module.

According to an exemplary embodiment of the present invention, there is provided a thermoelectric module, including: an insulating sealing part formed on portions of a thermoelectric module part or the entirety thereof, the thermoelectric module part including thermoelectric elements, electrodes, and substrates.

The insulating sealing part may include: an outer insulating sealing part on which the thermoelectric elements, the electrodes, and the substrates are formed; and an inner insulating sealing part which is space between the thermoelectric elements.

When the insulating sealing part is formed on portions of the thermoelectric module part, the insulating sealing part may be formed on the module part, except portions of the substrates to which radiating plates are attached.

The insulating sealing part may be coated with parylene.

The parylene may include at least one selected from dimers represented by the following formulas.

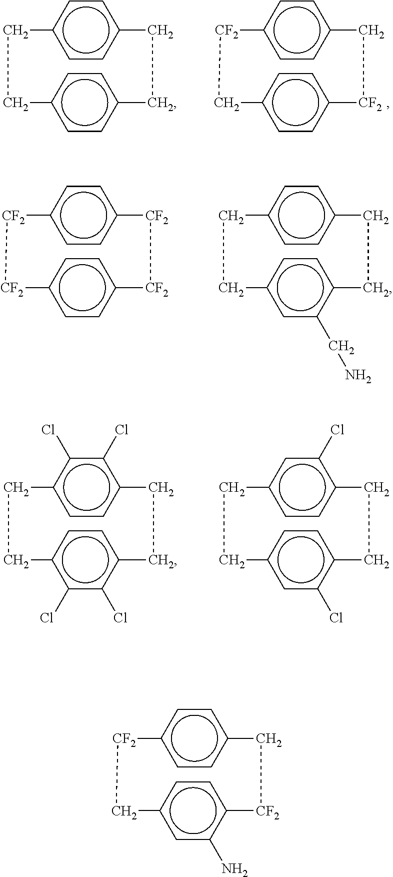

The insulating sealing part may have a thickness of 0.5 to 15 μm.

According to another exemplary embodiment of the present invention, there is provided a method of sealing a thermoelectric module, the method including: manufacturing a thermoelectric module by bonding thermoelectric elements between metal electrodes; and insulating and sealing portions of the thermoelectric module and the entirety thereof.

The insulating sealing may be parylene coating.

The parylene coating may include: vaporizing parylene powder in a dimer form; producing the vaporized powder in a monomer form through a pyroylsis; and changing the monomer form into a polymer form and depositing the polymer form.

The parylene coating may be performed at room temperature by a vacuum deposition method.

### BRIEF DESCRIPTION OF THE DRAWINGS

FIG. 1 is a diagram showing a structure of a general thermoelectric module including substrates, electrodes, and thermoelectric elements;

FIG. 2 is a diagram showing an example in which the thermoelectric module according to the related art is sealed with silicon or epoxy;

FIG. 3 is a diagram showing a structure of a thermoelectric module including an insulating sealing part according to an exemplary embodiment of the present invention; and

FIG. 4 is a diagram showing a process of coating parylene according to an exemplary embodiment of the present invention.

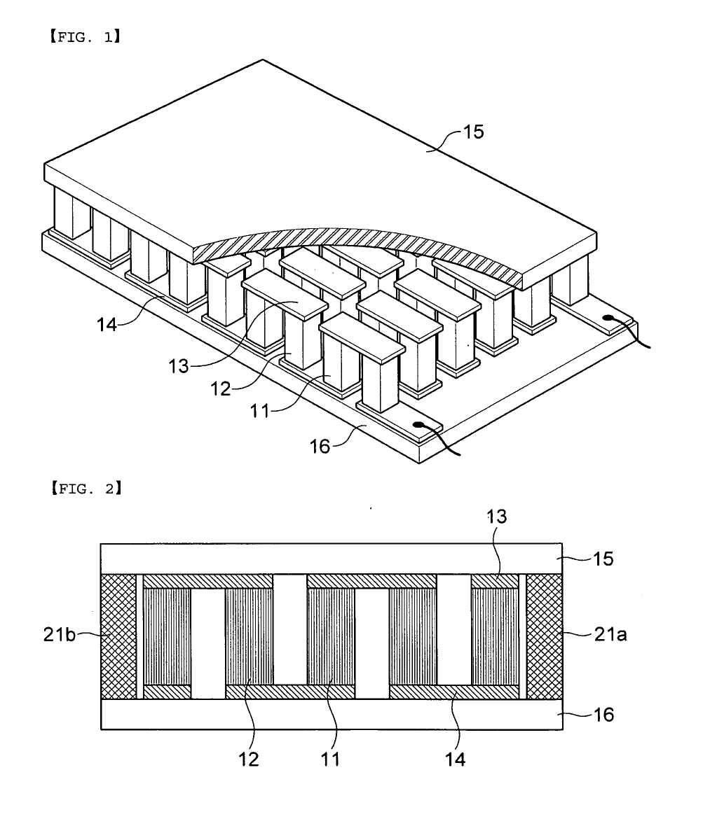

### DESCRIPTION OF THE PREFERRED EMBODIMENTS

Hereinafter, exemplary embodiments of the present invention will be described in detail with reference to the accompanying drawings.

Terms used in the specification are used to explain specific embodiments and not to limit the present invention. As used herein, the singular forms are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In the drawings, the size and the thickness of the apparatus may be exaggerated for the convenience. Like reference numerals denote like elements throughout the specification. The term ‘and/or’ includes a combination of a plurality of items or any one of a plurality of terms.

Terms used in the specification, ‘first’, ‘second’, etc. can be used to describe various elements, components, regions, layers and/or parts, but the elements, components, regions, layers and/or parts are not to be construed as being limited to the terms. These terms are only used to differentiate one element, component, region, layer or part from other regions, layers, or parts. Therefore, first element, component, region, layer or part may also refer to second element, component, region, layer or part, without diverting from the teachings of the present invention.

The present invention relates to a thermoelectric module capable of preventing moisture from being penetrated thereinto by including an insulating sealing part on portions of the thermoelectric module or the entirety thereof, the thermoelectric module including thermoelectric elements, electrodes, and substrates.

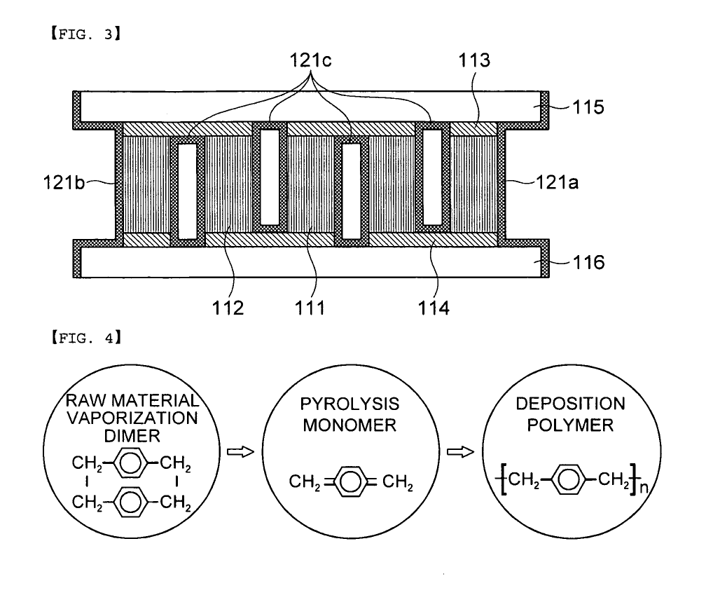

FIG. 3 is a diagram showing a structure of a thermoelectric module including an insulating sealing part according to an exemplary embodiment of the present invention.

Referring to FIG. 3, as the thermoelectric elements, N-type semiconductors 111 and P-type semiconductors 112 are generally used. A module is configured by arranging a plurality of N-type semiconductors 111 and P-type semiconductors 112, which form pairs, on a plane and then connecting them again in series using metal electrodes 113 and 114. The metal electrodes 113 and 114 are each formed on substrates 115 and 116.

The present invention includes insulating sealing parts 121a and 121b formed on portions of the thermoelectric module having the configuration as described above or the entirety thereof. The insulating sealing parts 121a and 121b are formed outside the thermoelectric module including the thermoelectric elements, the electrodes, and the substrates, and the insulating sealing parts 121c are formed inside the thermoelectric module, that is, space between thermoelectric elements 111 and 112.

When the thermoelectric module is coated with parylene, which is a new material having insulation, the parylene is penetrated between the thermoelectric elements to form an insulating separator 121c as shown in FIG. 3. The insulating separator 121c efficiently prevents corrosion due to water adsorption, thereby making it possible to improve reliability of the thermoelectric module.

The present invention can include the insulating sealing parts formed outside and inside the thermoelectric module, since the insulating sealing part is coated with parylene.

The insulating sealing part of the present invention is coated with parylene by a vacuum deposition method to form parylene films outside and inside the thermoelectric module.

The parylene coating has excellent insulation with high high-K, low dielectric constant, a low decomposition rate and is highly waterproof since it completely provides a sealing coat that prevents minimal adsorption of moisture.

In addition, the parylene coating has excellent corrosion resistance and chemical resistance since it is hardly affected by most of the chemicals such as acid, alkali, solvent or the like and also has excellent thermal stability in which thermal or mechanical deformation thereof or the property thereof is not changed in a range of −200 to 150° C.

In addition, the parylene coating has excellent penetration to enable to perform a uniform coating on minute cracks or inside holes as well as surface and to control a thickness of a coating layer.

In addition, the parylene coating is a polymer reaction in a vacuum state, such that pin-holes or air bubbles which are generated in a liquid-phase coating are not generated, thereby making it possible to provide a structurally stable coating layer.

In addition, the coating is performed, while being in a vacuum state, such that the coating may be applied to all of shapes, that is, from a simple shape to a complicated shape, thereby having no limitation in shapes. In addition, the parylene is a material which is environment-friendly enough to be approved by FDA and harmless to a human body. Further, the parylene has excellent permeability such that no change in appearance prior to or posterior to the coating thereof is required, and has excellent surface lubrication property posterior to the coating thereof and has little adsorption of minute dusts or oil components having viscosity.

Therefore, the present invention uses the parylene coating having several properties as described above, thereby making it possible to solve the problems of the epoxy or silicon coating according to the related art.

The parylene used in the parylene coating according to the present invention may include at least one selected from dimers represented by the following formulas.

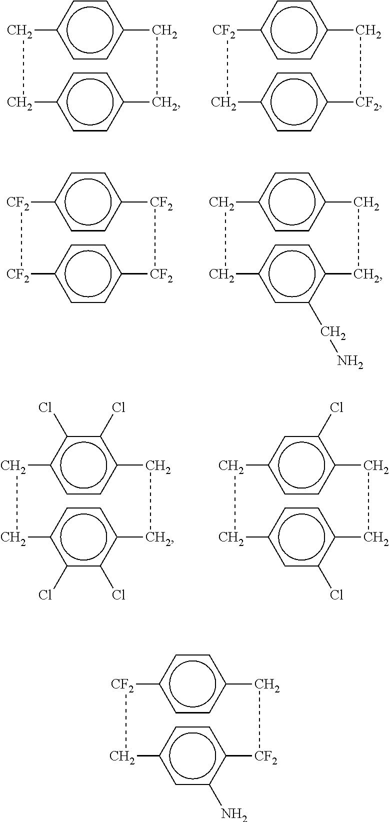

A raw material for the dimer represented by the formula may be poly-para-xylylene and at least one of the dimers or a mixture thereof in which at least two dimers are mixed may be used.

In other words, at least one or two or more dimers in an N-type in which there is no chlorine bonding, a C-type in which one chlorine element is bonded to two benzene rings, a D-type in which each of chlorine elements is bonded to two benzene rings, a F-type in which one of two CH₂ bondings is substituted by fluorine (F) instead of hydrogen (H), a HT-type in which two CH2 bondings are substituted by fluorine (F) instead of hydrogen (H), an A-type in which NH₂ is bonded to any one of two benzene rings, an AM-type in which CH₂-NH₂ is bonded to any one of two benzene rings, according to bonding degree of chlorine onto the benzene rings, may be mixed.

When the insulating sealing part is formed using the parylene, the insulating sealing part may have a thickness of about 0.5 to 15 μm. When the insulating sealing part has a thickness below 0.5 μm, the thickness thereof is too thin, such that it is difficult to expect sealing effects for insulation and prevention of moisture penetration. When the insulating sealing part has a thickness exceeding 15 μm, the coating part may become cracked and more time may be taken in coating thereof as the thickness becomes thick to cause increase in costs, such that it is not preferable.

When the insulating sealing part is formed on portions of the thermoelectric module part, the insulating sealing part may be formed on the module part, except for portions of the substrates to which radiating plates are attached.

However, when the insulating sealing part has a very thin thickness, the insulating sealing part may also be formed on the substrates to which the radiating plates are attached. Therefore, the insulating sealing part may also be formed over the thermoelectric module part.

Meanwhile, the present invention also provides a method of sealing a thermoelectric module using the parylene coating. The method of sealing a thermoelectric module may include manufacturing a thermoelectric module by bonding thermoelectric elements between metal electrodes; and insulating and sealing portions the thermoelectric module or the entirety thereof.

In other words, according to the related art, a process of forming a sealing part is included during a process of manufacturing a thermoelectric module; however, according to the present invention, a thermoelectric module is manufactured and then an insulating sealing part is formed on portions of the thermoelectric module or the entirety thereof.

Therefore, according to the present invention, the thermoelectric module is manufactured and is input into a vacuum chamber to be subjected to the parylene coating collectively, thereby making it possible to form the insulating sealing part on a desired portion of the thermoelectric module part.

The parylene coating may be performed by including vaporizing parylene powder in a dimer form represented by the formula; producing the vaporized powder in a monomer form through pyrolysis; and changing the monomer form into a polymer form and depositing the polymer form on the insulating sealing part.

The parylene coating is a method capable of forming a transparent coating film by depositing gas-phase powder at room temperature in a vacuum state.

The parylene coating, which is performed by using a chemical vapor deposition (CVD), uses equipment configured of three parts, i.e., a vaporizer, a pyrolizer, and a deposition chamber.

The parylene coating process is shown in FIG. 4. More specifically reviewing the parylene coating process with reference to FIG. 4, when dimers represented by the formula are mounted on a vaporizer in a powder form using a raw material, the dimers are subjected to a sublimation process in which the powder is changed into a gas-phase at temperature of about 120 to 180° C. The dimers changed into gas are decomposed into a monomer form by passing through the pyrolizer heated at temperature of about 680 to 720° C. In addition, the gas decomposed into a monomer form is changed into a polymer form, that is, poly-para-xylylene, thereby forming a coating film.

The change in structural formula of parylene through the parylene coating process is as shown in FIG. 4. First, the parylene used as a raw material has a dimer form represented by the formula and then has a monomer form by being subjected to a pyrolysis. Finally, the parylene monomer in a unstable state is deposited on a mother substrate in a polymer form to be stabilized. In the case of the parylene coating according to the present invention, the parylene in a monomer form is changed into a polymer form, while being deposited, such that neither separate curing process for polymerization nor thermal stress are needed. Compared with the related art in which a separate curing process using epoxy or the like is needed, the present invention can reduce manufacturing costs by simplifying the manufacturing process.

In addition, the parylene coating according to the present invention using a vacuum deposition process at room temperature can be performed at a lower temperature (about 35° C.) as compared to CVD/PVD/sputtering methods according to the related art. Further, the parylene coating is a type of coating in which gas is bonded to an object throughout the entire region of a chamber, such that the coating may be performed on a plurality of samples at one time (lowering manufacturing costs). Further, the parylene coating does not have a coating directionality, such that the inside of the thermoelectric module can be entirely coated in a finished product state.

During the parylene coating, a primer treatment or a solution dipping process may also be added in order to selectively improve adhesion.

The parylene used in the present invention has very high resistance and has no pin-holes, such that it is not electrolyzed by applied voltage and current. As a result, the parylene prevents moisture from being penetrated and protects the electrodes even in a flooded state, thereby making it possible to perform a remarkable waterproof function at the time of flooding.

Hereinafter, exemplary embodiments of the present invention will be described in more detail. The embodiments may be provided to completely disclose the present invention and allow those skilled in the art to completely know the scope of the present invention. The embodiments disclosed in the specification may be modified in various forms, but are not limited to the spirit and scope of the present invention. Rather, these embodiments may be provided so that this disclosure will be thorough and complete, and will fully convey the scope of the invention to those skilled in the art.

### Example 1

A thermoelectric module was manufactured by bonding thermoelectric elements between metal electrodes. The thermoelectric module was mounted within a chamber for parylene coating. The parylene coating according to the present invention was performed at room temperature of about 35° C.

In addition, in order to perform the parylene coating, N-type parylene dimers not containing chlorine in the formula were mounted, in a powder form, in a vaporizer of equipment configured of three parts, i.e., a vaporizer, a pyrolizer, and a deposition chamber. The parylene dimers in the powder form was sublimated into dimers in a gas-phase at temperature of about 150° C.

The dimers changed into gas were decomposed into a monomer form by passing through the pyrolizer heated at temperature of about 700° C. In addition, the parylene decomposed in the monomer form was passed through a final vacuum chamber to form insulating sealing parts (a thickness of 10 μm) coated with poly-para-xylylene inside and outside the thermoelectric module, as shown in FIG. 3.

### Comparative Example 1

A thermoelectric module was manufactured by bonding thermoelectric elements between metal electrodes.

Epoxy (B-stage) was injected into edge portions of the thermoelectric module using a dispenser and was cured, thereby forming a sealing part.

### Comparative Example 2

A thermoelectric module was manufactured by bonding thermoelectric elements between metal electrodes.

Silicon was injected into edge portions of the thermoelectric module using a dispenser and was cured, thereby forming a sealing part.

### Experimental Example

Water vapor transmission rate and water adsorption of the thermoelectric module including the sealing part obtained in Example 1 and Comparative Examples 1 and 2 were measured as follows and the results thereof were shown in Table 1.
Water vapor transmission rate, g.mm/d.day): It was measured based on ASTM E 96 (90% RH, 37° C.)
Water adsorption, %, after 24 hours): It was measured by dipping the thermoelectric module in moisture for 24 hours based on ASTM D 570.

TABLE 1

| | | Comparative | Comparative |
|---|---|---|---|
| | Example 1 | Example 1 | Example 2 |
| Water vapor | 0.59 | 0.94 | 1.7~47.5 |
| transmission rate | | | |
| (g.mm/m².day) | | | |
| Water adsorption (%) | <0.1 | 0.05~0.10 | 0.1 |

As shown from the results in Table 1, it can be appreciated from Example 1 according to the present invention in which the insulating sealing parts on which the parylene coating is performed are provided outside and inside the thermoelectric module, the water adsorption thereof is equivalent to or more excellent than that of Comparative Examples 1 and 2 in which epoxy or silicon is used.

In addition, it can be appreciated that the water vapor transmission rate of Example 1 is remarkably improved as compared to that in the case when epoxy or silicon is used.

Accordingly, it can be appreciated that the parylene coating according to the present invention easily forms the insulating sealing part outside as well as inside the thermoelectric module and the insulating sealing part serves as an insulating separator between elements to effectively prevent moisture from being penetrated from the outside. According to the present invention, when the thermoelectric module is coated with parylene, which is a new material having insulation, the parylene is penetrated between the thermoelectric elements to form an insulating separator. The insulating separator efficiently prevents corrosion due to water adsorption, thereby making it possible to improve reliability of the thermoelectric module.

In the case of the silicon or epoxy sealing according to the related art, automation thereof is difficult and there are many variations reflecting the workers manual labor. However, in the case of the parylene coating, the coating may be collectively performed in a chamber to have high reliability in a product and high efficiency in a manufacturing process.

In addition, in the case of the parylene coating, a separate curing time is not needed and void, which may be generated at the time of silicon or epoxy sealing according to the related art, is not generated, thereby making it possible to improve reliability of a product.

While the present invention has been shown and described in connection with the exemplary embodiments, it will be apparent to those in the art that modifications and variations can be made without departing from the spirit and scope of the invention as defined by the appended claims.

What is claimed is:

1. A thermoelectric module comprising:
an insulating sealing part formed on portions of a thermoelectric module part or the entirety thereof, the thermoelectric module part including thermoelectric elements, electrodes, and substrates.

2. The thermoelectric module according to claim 1, wherein the insulating sealing part includes:
an outer insulating sealing part on which the thermoelectric elements, the electrodes, and the substrates are formed; and
an inner insulating sealing part which is space between the thermoelectric elements.

3. The thermoelectric module according to claim 1, wherein when the insulating sealing part is formed on portions of the thermoelectric module part, the insulating sealing part is formed on the module part, except for portions of the substrates to which radiating plates are attached.

4. The thermoelectric module according to claim 1, wherein the insulating sealing part is coated with parylene.

5. The thermoelectric module according to claim 4, wherein the parylene includes at least one selected from dimers represented by the following formulas.

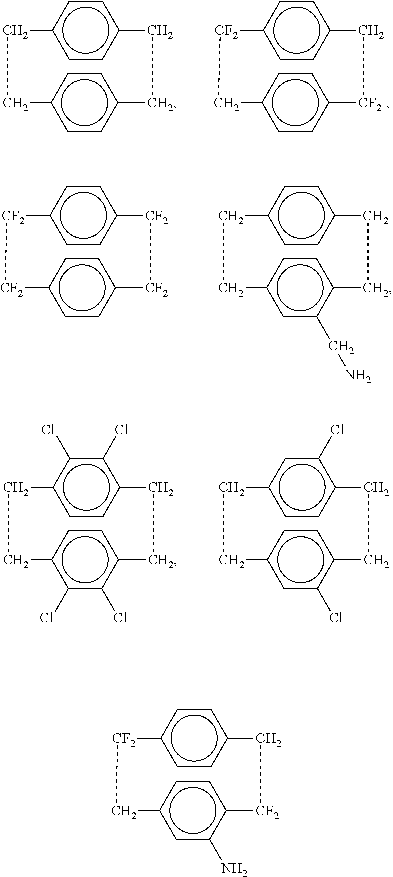

6. The thermoelectric module according to claim 1, wherein the insulating sealing part has a thickness of 0.5 to 15 μm.

7. A method of sealing a thermoelectric module, the method comprising:
manufacturing a thermoelectric module by bonding thermoelectric elements between metal electrodes; and
insulating and sealing portions of the thermoelectric module and the entirety thereof.

8. The method according to claim 7, wherein the insulating sealing is parylene coating.

9. The method according to claim 8, wherein the parylene coating includes:
vaporizing parylene powder in a dimer form;
producing the vaporized powder in a monomer form through a pyroylsis; and
changing the monomer form into a polymer form and depositing the polymer form.

10. The method according to claim 9, wherein the parylene coating is performed at room temperature by a vacuum deposition method.
